(19) United States
(12) Patent Application Publication
(10) Pub. No.: US 2024/0306351 A1
(43) Pub. Date: Sep. 12, 2024

(54) HEAT SINK FOR WIRING DEVICE

(71) Applicant: Hubbell Incorporated, Shelton, CT (US)

(72) Inventors: John E. Brower, Fairfield, CT (US); Brian Chia, Cheshire, CT (US); Jian Hua Li, Bayside, NY (US)

(21) Appl. No.: 18/599,855

(22) Filed: Mar. 8, 2024

Related U.S. Application Data
(60) Provisional application No. 63/451,397, filed on Mar. 10, 2023.

(51) Int. Cl. H05K 7/20; H01R 13/70; H02J 7/00; H05K 5/02; H05K 7/14; H01R 27/02

(52) U.S. Cl. CPC H05K 7/209; H01R 13/70; H02J 7/0042; H05K 5/0213; H05K 7/1427; H01R 27/02

(57) ABSTRACT

A wiring device including an enclosure including a front cover and a rear cover, a first printed circuit board (PCB) disposed within the enclosure, a first direct current (DC) port, a plurality of power electronics supported by a surface of the first PCB and configured to provide power to the first DC port, and a heat sink in direct contact with at least one of the plurality of power electronics and disposed within an interior of the rear cover.

### RELATED APPLICATIONS

This application claims priority to U.S. Provisional Patent Application No. 63/451,397, filed Mar. 10, 2023, the entire contents of which are hereby incorporated by reference.

### FIELD

The present disclosure relates generally to the thermal management of wiring devices that include direct current (DC) output ports.

### SUMMARY

One aspect of the present disclosure provides a wiring device including an enclosure including a front cover and a rear cover, a first printed circuit board (PCB) disposed within the enclosure, a first direct current (DC) port, a plurality of power electronics supported by a surface of the first PCB and configured to provide power to the first DC port, and a heat sink in direct contact with at least one of the plurality of power electronics and disposed within an interior of the rear cover.

Another aspect of the present disclosure provides an electrical receptacle including a rectifier configured to output power at a first direct current (DC) voltage level, a transformer configured to convert the power from the first DC voltage level to a second DC voltage level, the transformer connected to at least one switching device, at least one DC output port configured to receive power from the converter at the second DC voltage level, a microcontroller having an electronic processor configured to control a frequency at which the at least one switching device is operated, a heat sink in direct contact with the transformer.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the application will become apparent by consideration of the detailed description and accompanying drawings.

### BRIEF DESCRIPTION OF THE DRAWINGS

FIG. 1 illustrates a front view of a wiring device, or electrical receptacle, according to some embodiments.

FIG. 2 illustrates a side view of the receptacle of FIG. 1, according to some embodiments.

FIG. 3 illustrates a front view of the receptacle of FIG. 1 with a front cover removed, according to some embodiments.

FIGS. 4A and 4B illustrate perspective views of a secondary PCB and a third PCB included in the receptacle of FIG. 1, according to some embodiments.

FIG. 5 illustrates a side view of the receptacle of FIG. 1 with a front cover and a rear cover removed, according to some embodiments.

FIG. 6 illustrates a top view of a primary PCB included in the receptacle of FIG. 1, according to some embodiments.

FIG. 7 illustrates a perspective view of the primary board, power electronics, and a heat sink included in the receptacle of FIG. 1, according to some embodiments.

FIG. 8 illustrates a rear view of the receptacle of FIG. 1, according to some embodiments.

FIG. 9 illustrates a rear view of the receptacle of FIG. 1 with a rear cover removed, according to some embodiments.

FIG. 10 illustrates a perspective view of a heat sink included in the receptacle of FIG. 1, according to some embodiments.

FIG. 11 is a block diagram of a charging circuit included in the receptacle of FIG. 1, according to some embodiments.

FIG. 12 is a block diagram of a charging circuit included in the receptacle of FIG. 1, according to some embodiments.

FIG. 13 is a block diagram of a charging circuit included in the receptacle of FIG. 1, according to some embodiments.

FIG. 14 is a block diagram of a charging circuit included in the receptacle of FIG. 1, according to some embodiments.

### DETAILED DESCRIPTION

Before any embodiments of the application are explained in detail, it is to be understood that the application is not limited in its application to the details of construction and the arrangement of components set forth in the following description or illustrated in the following drawings. The application is capable of other embodiments and of being practiced or of being carried out in various ways.

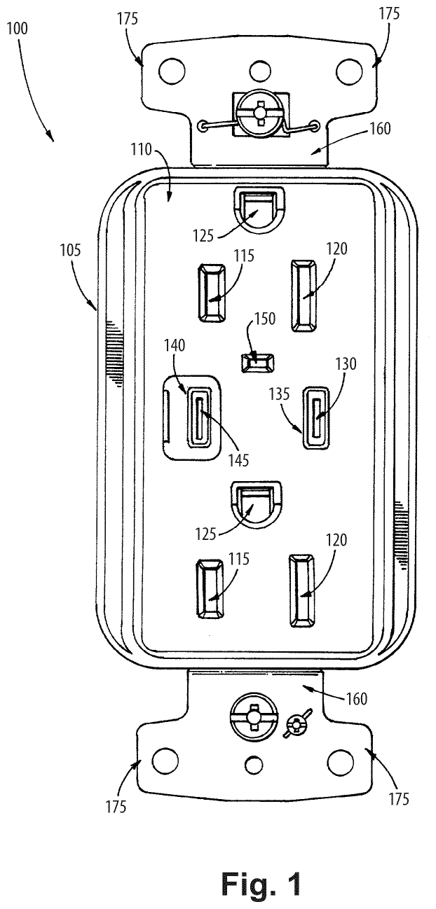

FIG. 1 illustrates a frontal view of a wiring device, or electrical receptacle, 100 according to some embodiments of the present disclosure. The receptacle 100 includes a front cover 105 having an outlet face 110 with phase, or hot, openings 115, neutral openings 120, and ground openings 125. In some embodiments, the outlet face 110 includes more or fewer phase, neutral, and ground openings than the illustrated embodiment. In some embodiments, the outlet face 110 does not include any phase, neutral, and ground openings. In such embodiments, the outlet face 110 only includes openings that accommodate (universal serial bus) USB ports.

As shown in FIG. 1, the face 110 further includes a first opening 130 accommodating a first direct current (DC) charging port, or USB port, 135. The face 110 further includes second opening 140 accommodating a second DC charging port, or USB port, 145. In some embodiments, such as the illustrated embodiment, the first USB port 135 is a USB type C (USB-C®) port and the second USB port 145 is a USB type C (USB-C®) port. In some embodiments, the first and second USB ports 135, 145 are implemented as other types of USB ports. For example, the first and second USB ports 135, 145 may be implemented as any combination of USB-A®, USB-B®, USB-C®, mini USB-A®, mini USB-B®, micro USB-A®, micro USB-B®, and/or other types of USB ports. In some embodiments, the outlet face 110 is configured to accommodate more than two USB ports included in receptacle 100. For example, the outlet face may include three, four, five, or more USB ports. In some embodiments, the outlet face 110 is configured to accommodate a single USB port included in receptacle 100. In some embodiments, the USB ports are implemented as other types of direct current (DC) charging ports. As will be described in more detail below, the first and second USB ports 135, 145 are respectively configured to deliver 50-60 watts of power, or more, to a load. For example, the first USB port 135 may deliver 50-60 watts of power for charging a laptop connected to the first USB port 135. Likewise, the second USB port 145 may deliver 50-60 watts of power for charging a laptop connected to the second USB port 145. In some instances, only one of the first and second USB ports 135, 145 may deliver 50-60 watts of a power at a time. In some instances, the first and second USB ports 135, 145 may combine to deliver more than 50-60 watts of power at a time,

In some embodiments, the outlet face 110 further includes one or more additional openings 150. The one or more additional openings 150 accommodate indicators, such as but not limited to, various colored light-emitting diodes (LEDs). In some embodiments, the one or more additional openings 150 accommodate bright LEDs used, for example, as a charging indicator. In some embodiments, the one or more additional openings 150 accommodate bright LEDs used, for example, as a nightlight. In some embodiments, the one or more additional openings 150 accommodate a photoconductive photocell used, for example, to control the nightlight LEDs. In some embodiments, the one or more additional openings 150 provide access to a set screw for adjusting a photocell device or a buzzer in accordance with this, as well as other, embodiments.

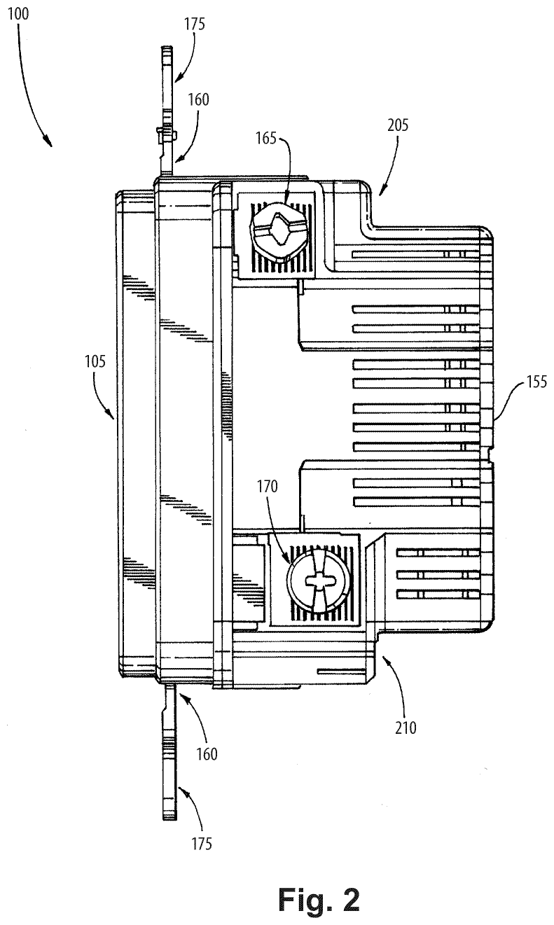

FIG. 2 illustrates a side view of the receptacle 100 according to some embodiments of the present disclosure. As shown, the receptacle 100 further includes a rear cover 155 that is secured to the front cover 105. In some embodiments, the front cover 105 is removably (or releasably) coupled to the rear cover 155. In some embodiments, the front cover 105 is secured to the rear cover 155 by a plurality of fasteners (not shown or enumerated). In some embodiments, the front cover 105 is secured to the rear cover 155 by a snap-fit connection. The receptacle 100 further includes a plurality of terminals for connecting electrical conductors and a ground yoke/bridge assembly 160. The plurality of terminals includes a phase (hot) terminal 165 and a neutral (white) terminal 170. In some embodiments, the phase and neutral terminals 165, 170 are located on a first side of the rear cover 155 and respectively include screws for securing terminal conductors. In other embodiments, the phase and neutral terminals 165, 170 are implemented using a snap-fit connection. The receptacle 100 may further include a ground terminal that is electrically connected to the ground yoke/bridge assembly 160, which includes standard mounting cars 175 that protrude from ends of the receptacle 100. The entire enclosure of the receptacle 100, which includes the front cover 105 and the rear cover 155, is sized and shaped to fit within a standard junction box and/or switch box. For example, as shown in FIG. 2, the rear cover 155 includes first and second indented portions 205, 210 that reduce the overall size of the receptacle 100, thereby allowing the receptacle 100 to be received by an industry standard junction box and/or an industry standard switch box (for example, a one gang rectangular junction box).

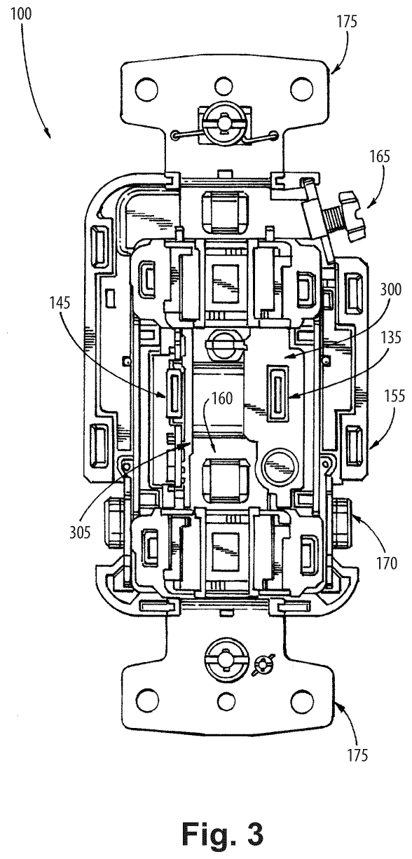

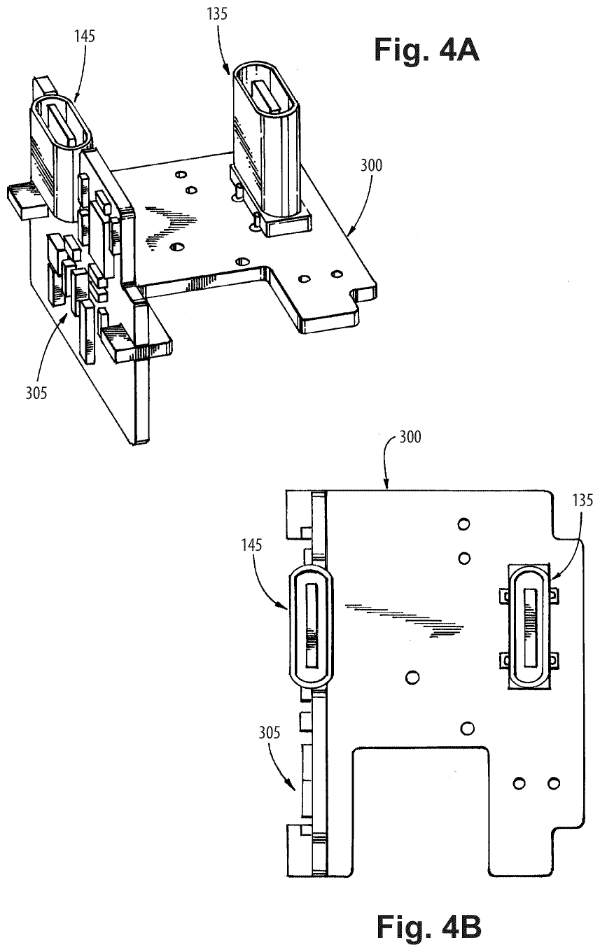

FIG. 3 illustrates a front view of the receptacle 100 in which the front cover 105 has been removed to expose some of the internal components included in receptacle 100. As shown, the receptacle 100 includes a secondary printed circuit board (PCB), or secondary board, 300 and a third board 305. The secondary board 300 supports the first and second USB ports 135, 145. In addition, the secondary board 300 provides control and physical support for one or more LED indicators accommodated within the one or more additional openings 150. The third board 305 also supports the second USB port 145 and provides control and physical support for one or more additional components of the receptacle 100. As shown, the secondary board 300 extends in a direction that is parallel to the face 110 and the third board extends in a direction that is perpendicular to the face 110. FIGS. 4A-4B illustrate perspective views of the secondary board 300 and the third board 305.

In some embodiments, the secondary board 300 and/or the third board 305 may further provide physical support for one or more control electronics configured to control the voltage and/or current output of the first and second USB ports 135, 145. For example, the secondary board 300 and/or the third board 305 may include one or more microchips, microcontrollers, switching devices, and/or logic elements. In some embodiments, switching devices supported by the secondary board 300 and/or the third board 305 are formed of silicon carbide (SiC). In other embodiments, switching devices supported by the secondary board 300 and/or the third board 305 are formed of gallium nitride (GaN). In yet other embodiments, the switching devices supported by the secondary board 300 and/or third board 305 are formed of other wide bandgap semiconductors.

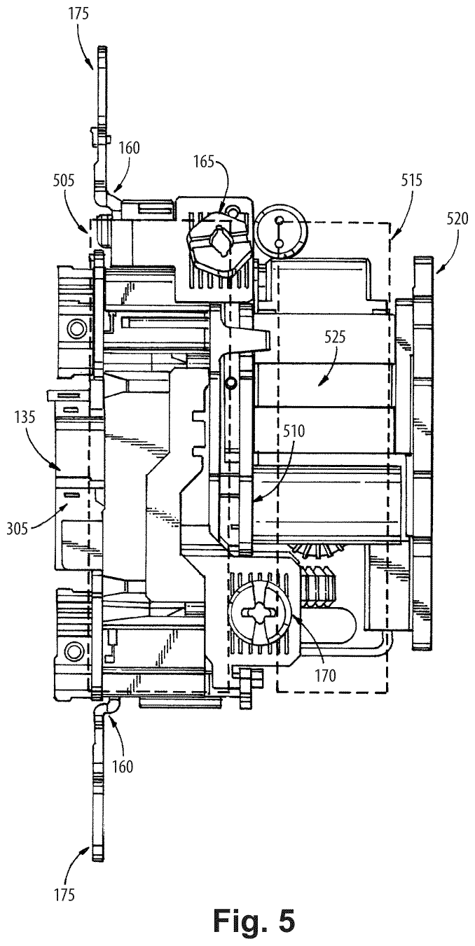

FIG. 5 illustrates a side view of the receptacle 100 in which the front cover 105 and the rear cover 155 have been removed to expose some of the internal components included in receptacle 100. As shown, the receptacle 100 further includes, among other things, a protection circuit 505, which is indicated by a dashed box, a primary printed circuit board, or primary board, 510, a plurality of power electronics 515, which is indicated by a dashed box, and a heat sink 520. The protection circuit 505, which may be implemented as one or more of a ground fault circuit interrupter (GFCI) and/or an arc fault circuit interrupter (AFCI), is disposed between a front-facing surface of the primary board 510 and the front cover 105 (not shown in FIG. 5). The power electronics 515 are disposed within the rear cover 155 (not shown) between a rear-facing surface of the primary board 510 and the heat sink 520. The power electronics, which include a transformer 525, are used for powering the first and/or second USB ports 135, 145. As will be described in more detail below, the primary board 510 provides control and physical support for one or more components of the protection circuit 505, one or more of the power electronics 515, and additional working components included in the receptacle 100.

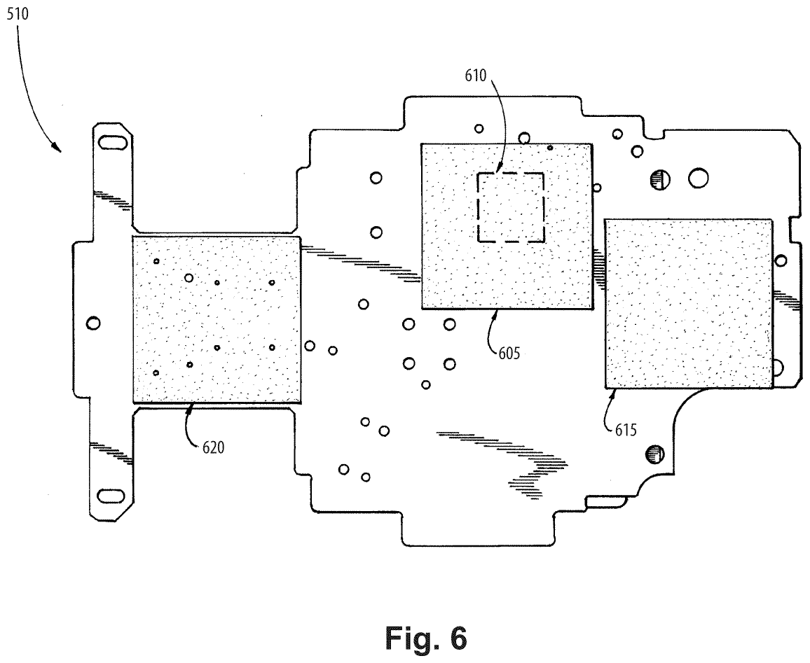

FIG. 6 illustrates a top view of the front surface of the primary board 510. As shown, the front surface provides support for a plurality of control electronics, such as a microcontroller 605, a first switch 610, a second switch 615, and an input bridge rectifier 620. In the illustrated embodiment, the first switch 610 is included in, or integrated within, the microcontroller 605. However, in other embodiments, the microcontroller 605 and the first switch 610 are implemented as separate components. In some embodiments, the front surface of the primary board 510 provides support for one or more additional microcontrollers and/or switches. Furthermore, it should be understood that the control electronics illustrated in FIG. 6 are not limited to placement on the front surface, as in some embodiments, some or all of the one or more control electronics are mounted to the rear surface of the primary board 510. Similarly, in some embodiments, some or all of the power and control electronics supported by the front surface of the primary board 510 are mounted to, or otherwise supported by, the rear surface of the primary board 510.

The microcontroller 605 is an integrated circuit device, such as a Microchip microcontroller that includes an electronic processor and a memory. In some embodiments, the microcontroller 605 is implemented as a PIC18F Microchip microcontroller. However, in other embodiments, the microcontroller 605 is implemented as another type of microcontroller. As will be described in more detail below, the microcontroller 605 is configured to control various operations of the receptacle 100. For example, the microcontroller 605 may be configured to control the delivery of charging power to one or more peripheral devices (e.g., smartphones, tablets, headphones, etc.) connected to the first and/or second USB ports 135, 145. As another example, the microcontroller 605 may be configured to control operation of the first and second switches 610, 615. As another example, the microcontroller 605 may be electrically connected to and configured to control operation of one or more control electronic components connected to the secondary board 300 (e.g., a second microcontroller, one or more switches, etc.) and/or the third board 305.

As will be described in more detail below, the first and second switches 610, 615 are included in a charging circuit and used to control an amount of DC charging power provided to one or more peripheral devices connected to the first and/or second USB ports 135, 145. For example, the first switch 610 may be used to control output of the transformer 525 and the second switch 615 may be used to control output of one or more secondary power supplies. As another example, both the first and second switches 610, 615 are used to control output of the transformer 525. In some embodiments, the microcontroller 605 is configured to control operation of both the first and second switches 610, 615. In some embodiments, a first microcontroller is configured to control operation of the first switch 610 and a second microcontroller is configured to control operation of the second switch 615. In some embodiments, one or more driving circuits (for example, gate drivers) are used to drive the first and second switches 610, 615 based on the signals from the microcontroller(s).

In some embodiments, the first switch 610, the second switch 615, and/or any other switching element included in the charging circuit of receptacle 100 are implemented as conventional silicon switches, such as traditional silicon metal oxide semiconductor field effect transistors (MOSFETs). However, the frequency and loss characteristics of conventional silicon switches impose a practical limit on the maximum power density of charging circuits, such as switch-mode converters, included in electrical receptacles. Moreover, the highest possible power that can be processed in a confined space (like that of an electrical box) is at or approaching the practical limit in present, conventional silicon switching devices.

Accordingly, in some embodiments, silicon switching devices included in the power charging circuit are replaced with wide bandgap semiconductor based devices, for example, GaN and/or SiC transistors and/or diodes. That is, in some embodiments, the first switch 610, second switch 615, and/or any switching element within the charging circuit that would benefit from reduced switching and conduction losses are implemented as GaN or SiC transistors or diodes. When compared to silicon, the chemistry of wide-bandgap materials, such as GaN or SiC, allows for reduced conduction and switching losses and higher frequency commutation. Therefore, GaN or SiC switching devices have a much greater power density than traditional silicon switching devices. Thus, the nominal switching frequency of the power converter may be increased to a desired point of optimization between acceptable switching loss (temperature rise) and overall size (reactive energy storage devices) when GaN and/or SiC switching elements are implemented in place of conventional silicon switching devices. Moreover, this effective increase in power density allows for greater throughput power in existing device profiles like wiring devices and wireless chargers. In such embodiments, the microcontroller 605 is configured to set a high primary switching frequency (e.g., 100 kHz and up) for the first switch 610, second switch 615, and/or other switching elements included in the charging circuit.

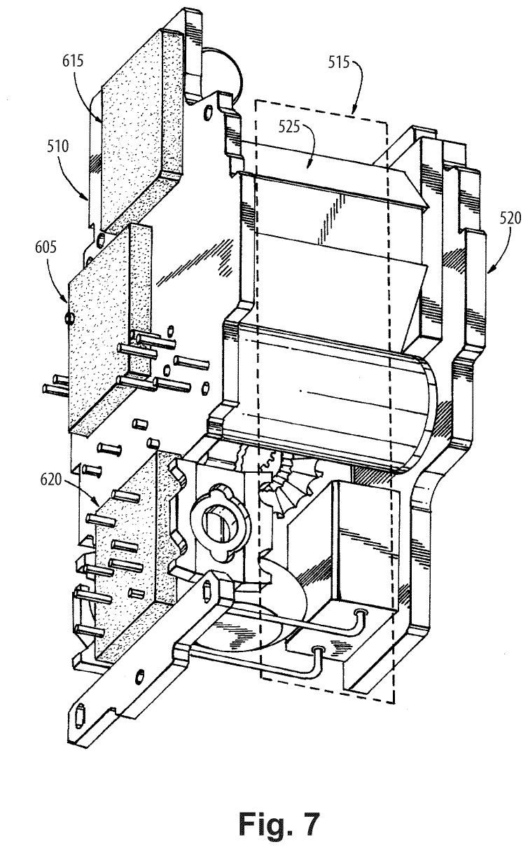

Referring back to FIG. 5, the power electronics 515 disposed between the rear surface of the primary board 510 and the heat sink 520 include various components, such as the transformer 525, one or more capacitors, one or more inductors, one or more switching devices, and/or one or more circuit interrupting devices, for powering the first and second USB ports 135, 145. As shown, at least one of the plurality of power electronics 515 is coupled to and/or supported by the rear surface of the primary board 510. In the illustrated embodiment, the transformer 525 is implemented as a discrete, wound transformer that protrudes outward from the rear surface of the primary board 510. However, in some embodiments, the transformer 525 is implemented as a linear transformer that is integrated with the primary board 510. In some embodiments, one or more of the plurality of power electronics 515 is supported by the front surface of the primary board 510, the secondary board 300, and/or the third board 305. FIG. 7 illustrates a perspective view of the plurality of power electronics 515 disposed between the primary board 510 and the heat sink 520.

As described above, the first and second USB ports 135, 145 are respectively configured to deliver 50-60 watts of power, or more, to a load. For example, the first USB port 135 may deliver 50-60 watts of power for charging a laptop connected to the first USB port 135. Likewise, the second USB port 145 may deliver 50-60 watts of power for charging a laptop connected to the second USB port 145. In some instances, only one of the first and second USB ports 135, 145 may deliver 50-60 watts of a power at one time. In some instances, the first and second USB ports 135, 145 may combine to deliver more than 50-60 watts of power at a time.

Since the first and/or second USB ports 135, 145 provide a relatively large amount of power (e.g., 50-60 watts or more) to connected loads, the plurality of power electronics 515 that power the first and second USB ports 135, 145, including the transformer 525 and/or the rectifier 620, dissipate large amounts of heat while the first and/or second USB ports deliver power to a connected load (e.g., a laptop). Accordingly, to prevent the working components of the receptacle 100 from overheating and/or becoming damaged while the first and/or second USB ports deliver power to a connected load, the heat sink 520 is arranged to transfer heat from the power electronics 515 to the exterior of the receptacle 100.

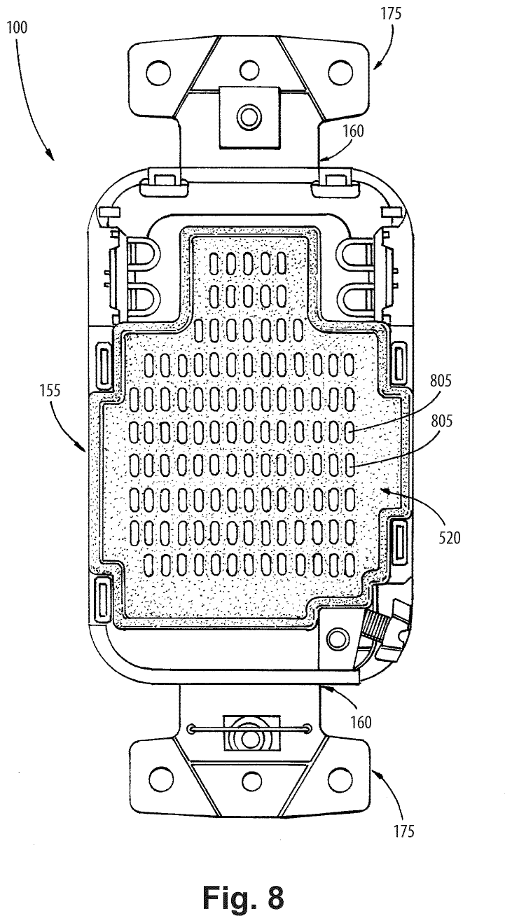

As shown in FIGS. 5 and 7, the heat sink 520 is directly coupled to at least one of the plurality of power electronics 515 to improve the heat transfer from the power electronics 515 and primary board 510 to the exterior of the receptacle. That is, the heat sink 520 is in direct contact with one or more of the power electronics 515, such as the transformer 525. Moreover, as shown in the rear view of the receptacle 100 illustrated in FIG. 8, the heat sink 520 is disposed within an interior of the rear cover 155 of the receptacle 100, for example, in contact with an interior surface of the rear cover 155. In this arrangement, the heat sink 520 conducts heat generated by the working components contained within the receptacle 100 to the exterior of the receptacle 100 through the plurality of ventilation holes 805 formed in the rear surface of the rear cover 155. By placing the heat sink 520 within the rear cover 155 of the receptacle 100 and in direct contact with the power electronics 515, the heat sink 520 is able to transfer larger amounts of heat from the interior of the receptacle 100 to the exterior of the receptacle 100 when compared to receptacle designs that do not include heat sinks or include heat sinks that are disposed on the exterior of the receptacle housing.

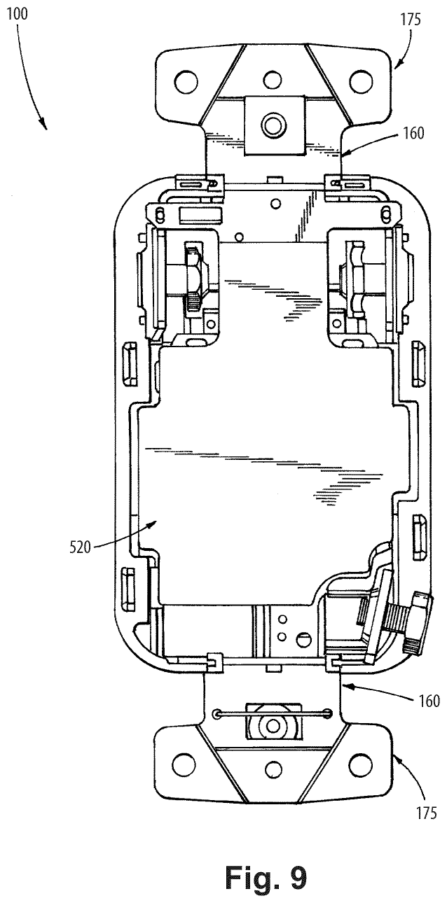

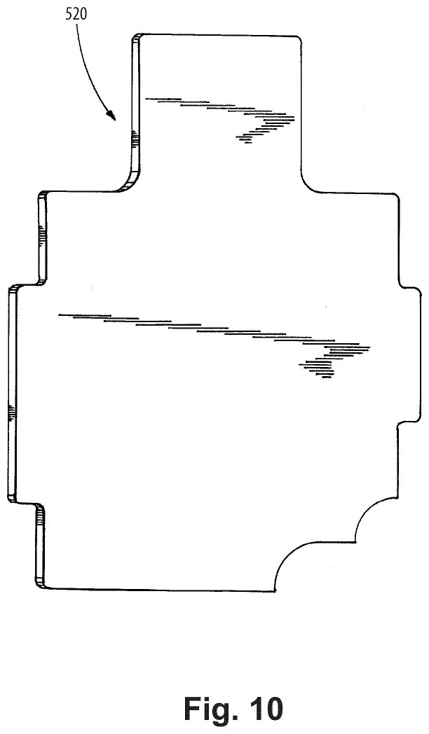

In some instances, the heat sink 520 is coupled to the power electronics 515 using a thermal adhesive material. In other instances, the heat sink 520 is pressed against the power electronics 515 without the use of a thermal adhesive. In some instances, the heat sink 520 is installed in the rear cover 155 using a friction fit. The heat sink 520 is formed of a material having a high thermal conductivity, such as but not limited to steel, aluminum, and/or copper. In some instances, the heat sink 520 is formed of a combination of one or more thermally conductive materials. FIG. 9 illustrates a rear view of the receptacle 100 in which the rear cover 155 is removed to expose the heat sink 520, and FIG. 10 illustrates a perspective view of the heat sink 520. In the illustrated embodiments of FIGS. 9 and 10, the surfaces of the heat sink 520 are flat. However, in some instances, the surfaces of the heat sink 520 include one or more of grooves, notches, indents, fins, and/or other physical features that improve the ability of the heat sink 520 to expel heat from the interior of the receptacle 100.

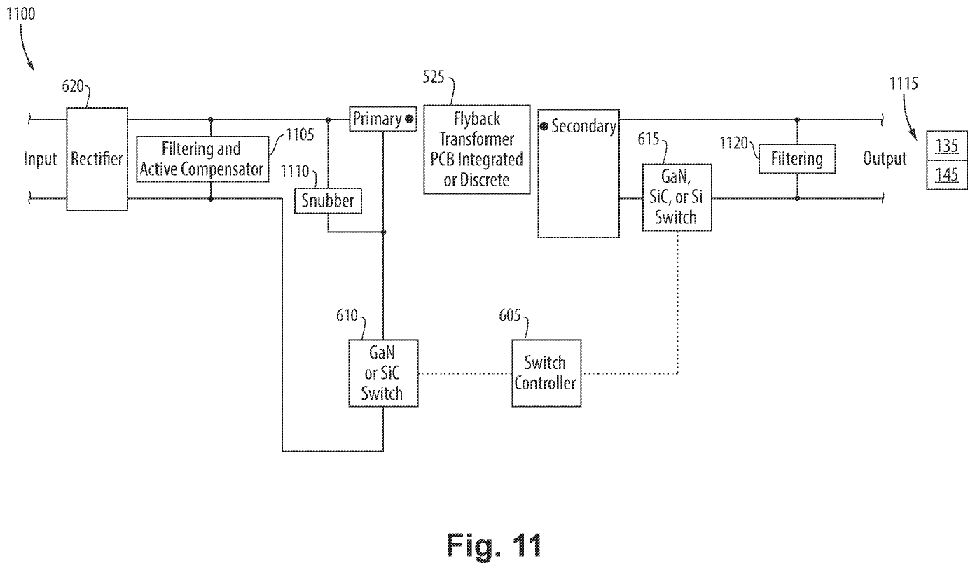

FIG. 11 illustrates an example block diagram of a charging circuit 1100 included in the receptacle 100, according to some embodiments. The charging circuit 1100 is used to provide power to one or more loads connected to the first and/or second USB ports 135, 145. The illustrated charging circuit 1100 is implemented using a switch-mode topology. However, it should be understood that in some embodiments, other power conversion topologies are used.

As shown, the charging circuit 1100 includes, among other things, the transformer 525, the microcontroller 605, the first switch 610, the second switch 615, and the rectifier 620. The rectifier 620 converts alternating current (AC) input power into DC power. DC power output by the rectifier 620 is filtered by an active compensator 1105 before being delivered to the primary side of transformer 525. The active compensator 1105 is configured to reduce voltage ripple on the input bus while also eliminating the need for traditional, bulky storage capacitors. Accordingly, the presence of the active compensator 1105 allows for smaller capacitors to be used in the charging circuit 1100, thereby freeing up significant space and increasing overall power density on the input side of the charging circuit 1100. In some embodiments, the active compensator 1105 is implemented as a standard configuration buck-boost based compensator topology; however, it should be understood that in some embodiments, the active compensator is implemented using other topologies. In some embodiments, the charging circuit 1100 further includes a snubber 1110 electrically connected in parallel with the primary side of transformer 525. In such embodiments, the snubber 1110 is configured to suppress voltage transient spikes at the primary side of transformer 525.

The transformer 525 is configured to output DC power at a voltage level to be provided directly to one or more peripheral devices connected to ports included in the output 1115, such as the first and second USB ports 135, 145. In some embodiments, the transformer 525 is configured to output power at a fixed voltage level, such as 5V. For example, the transformer is configured to output 50-60 watts of power, or more, at 5V to the load(s) connected to the first and/or second USB ports 135, 145. In other embodiments, the transformer 525 is configured to output power at various voltage levels. For example, the transformer 525 may be configured to output power at 2.5V, 3V, 5V, 10V, 15V, 20V, and/or etc. In such embodiments, the microcontroller 605 is configured to control, by the first switch 610 and/or the second switch 615, the voltage level and/or amount of current provided by the transformer 525 to the outputs (e.g., the first and second USB ports 135, 145).

As described above, in some embodiments, the transformer 525 is implemented as a flyback converter, for example, including a GaN and/or SiC switching device. In such embodiments, the transformer 525 may be implemented as a discrete, wound transformer or as a planar transformer integrated within the primary board 510. In some embodiments, the transformer 525 is implemented as other types of DC-DC converter topologies.

The charging circuit 1100 further includes a filtering circuit 1120 that is used to reduce output voltage ripple. As described above, the first and/or second switches 610, 615 may be implemented as GaN or SiC switching devices. GaN and SiC switching devices exhibit much lower switching power losses than conventional silicon switches. Thus, when switches 610, 615 are implemented as GaN and/or SiC switching devices, the switches 610, 615 may be operated at higher switching frequencies (e.g., 100 kHz and up) than conventional silicon switching devices without undergoing the typical degrees of thermal stress experienced by silicon switching devices. Moreover, as GaN and/or SiC switching devices are capable of operating at such high switching frequencies, the filtering circuit 1120 may be implemented using relatively small capacitors without sacrificing performance. Therefore, the cost and size of filtering circuit 1120 is reduced when the first switch 610, second switch 615, and/or any other switching elements included in the charging circuit 1100 are implemented as Gan or SiC switching devices.

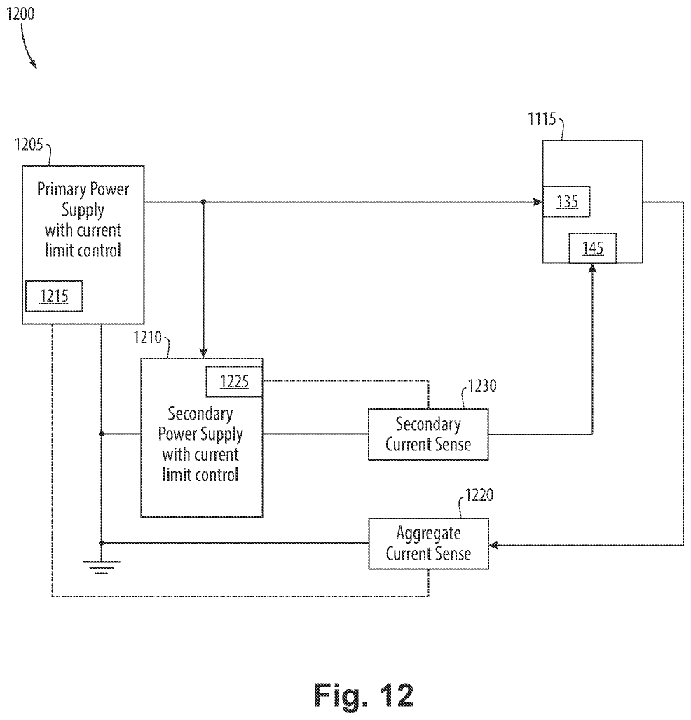

In some embodiments, the output 1115 of receptacle 100 is supplied with power directly from a primary power supply, such as the transformer 525. In other embodiments, the output 1115 is supplied with power from a combination of the primary power supply and one or more secondary power supplies. FIG. 12 illustrates a block diagram of a charging circuit 1200 included in receptacle 100 in which the output 1115 is supplied with power from a primary power supply 1205 and/or one or more secondary, or downstream, power supplies 1210.

In some embodiments, the primary power supply 1205 is implemented as the transformer 525, which additionally comprises any corresponding switching devices used to control transformer 525 (e.g., the first switch 610 and/or second switch 615). In other embodiments, the primary power supply 1210 is implemented as another known type of DC-DC power converter. As shown, the primary power supply 1205 is configured to provide power directly to the output 1115 and at least one downstream power supply 1210. In particular, the primary power supply 1205 is configured to provide power directly to at least one output port included in the output 1115. For example, in the illustrated embodiment, the primary power supply 1205 provides power directly to the first USB port 135 and the at least one downstream power supply 1210. However, in other embodiments, the primary power supply 1205 is configured to provide power directly to the at least one downstream power supply 1210, the first and/or second USB ports 135, 145, and/or additional output ports included in output 1115.

The primary power supply 1205 includes a first independent control mechanism 1215. In some embodiments, the first independent control mechanism 1215 is implemented as the microcontroller 605 in combination with one or more switching devices, such as the first and second switches 610, 615. In other embodiments, the first independent control mechanism 1215 is implemented as another type of microcontroller or logic circuit in combination with other switching devices not explicitly described herein. The charging circuit 1200 further includes an aggregate current sensing circuit 1220 that is configured to sense a combined current output by the primary power supply 1205 and the one or more downstream power supplies 1210.

The first independent control mechanism 1215 is configured to limit current output by the primary power supply 1205 to the sum of the primary power supply's 1205 maximum rated output current (e.g., 10 A, 200 A, etc.) and the combined rated output current (e.g., 5 A, 10 A, etc.) of all connected downstream power supplies 1210. For example, in operation, the first independent control mechanism 1215 is configured receive one or more current values sensed by the aggregate current sensing circuit 1220. Based on the received current value(s), the first independent control mechanism 1215 is configured to adjust the voltage and/or current output by the primary power supply 1205. Accordingly, the first independent control mechanism 1215 included in primary power supply 1205 is operable to regulate the amount of power output by the charging circuit 1200 based in part on a current provided directly to at least one output port included in output 1115 (e.g., the first USB port 135) and current provided directly to at least one of the downstream power supplies 1210.

As described above, the primary power supply 1205 is configured to provide power directly to at least one downstream power supply 1210. The downstream power supply 1210 is configured to convert power received from the primary power supply 1205 and output power directly to one of the output ports (e.g., the second USB port 145) included in output 1115. In some embodiments, the downstream power supply 1210 provides power to a respective output port, such as the second USB port 145, at a fixed voltage level (e.g., 5V, 10V, etc.). In other embodiments, the downstream power supply 1210 is operable to provide power to a respective output port at varying voltage levels (e.g., 1V-10V). In some embodiments, the downstream power supply 1210 is implemented as a flyback transformer. In other embodiments, the downstream power supply 1210 is implemented using other known DC-DC converter topologies such as a buck/boost converter, buck converter, or boost converters.

The downstream power supply 1210 includes a second independent control mechanism 1225 that is configured to control an amount of power provided by the downstream power supply 1210 to a respective output port (e.g., USB port 145) included in output 1115. In particular, the second independent control mechanism 1225 is configured to control power output by the downstream power supply 1210 based on current values sensed by a second current sensing circuit 1230. As shown in FIG. 12, the second current sensing circuit 1230 is configured to sense an amount of current that is provided by the downstream power supply 1210 to an individual output port (e.g., the second USB port 145) included in output 1115. In some embodiments, the second independent control mechanism 1225 is configured to limit the amount of current output by the downstream power supply 1210 to a value that is less than or equal to the current rating of the downstream power supply 1210. In other embodiments, the second independent control mechanism 1225 is configured to limit current output by the downstream power supply 1210 based on a current rating of a peripheral device connected to the output port receiving power from the downstream power supply 1210. Similar to the first independent control mechanism 1215, the second independent control mechanism 1225 may be implemented as a microcontroller, a logic circuit, and/or any other type of control device operable to control the switching elements included in the downstream power supply 1210.

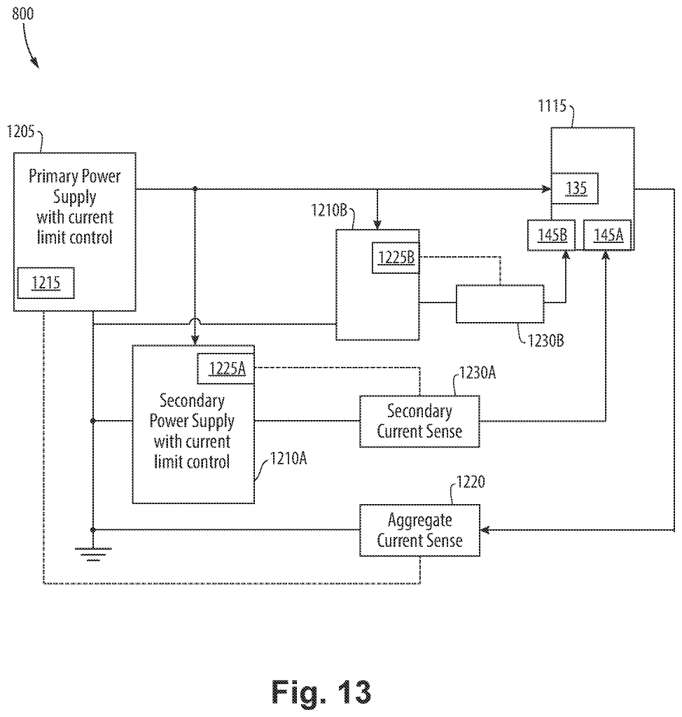

Although the charging circuit 1200 is illustrated as including only a single downstream power supply 1210, it should be understood that the charging circuit 1200 may include any number, N, of additional downstream power supplies. For example, FIG. 13 illustrates an embodiment in which a charging circuit 1200 includes first and second downstream power supplies 1210A, 1210B. As shown, each downstream power supply 1210A, 1210B is configured to receive power from the primary power supply 1205 and output power to a respective output port 145A, 145B included in output 1115. Moreover, an amount of power provided to each output port included in output 1115 is sensed by a respective current sensing circuit and provided to a respective independent control mechanism. For example, the amount of power provided by the first downstream power supply 1210A to output port 145A is sensed by the current sensing circuit 1230A. Accordingly, the independent control mechanism 1225A included in downstream power supply 1210A is operable to control output of the downstream power supply 1210A based on current values sensed by the current sensing circuit 1230A. Similarly, the amount of power provided by the second downstream power supply 1210B to output port 145B is sensed by the current sensing circuit 1230B. Accordingly, the independent control mechanism 1225B included in downstream power supply 1210B is operable to control output of the downstream power supply 1210B based on current values sensed by the current sensing circuit 1230B.

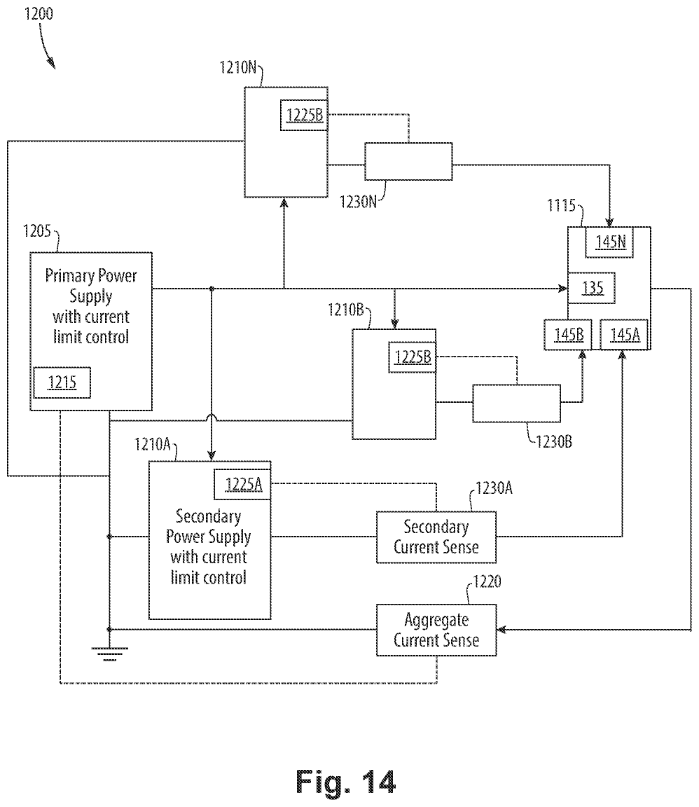

FIG. 14 illustrates a generalized embodiment of the charging circuit 1200. As shown, the output 1115 may include a first output port (e.g., USB output port 135) and number, N, of second output ports (e.g., USB output ports 145A-145N). In such an embodiment, the charging circuit 1200 may be configured to include the primary power supply 1205 and a plurality of downstream power supplies 1210A-1210N. Each one of the respective downstream power supplies 1210A-1210N receives power from the primary power supply 1205 and provides power to a respective one of the second output ports 145A-145N. For example, the first downstream power supply 1210A provides power directly to the second output port 145A, the second downstream power supply 1210B provides power directly to the second output port 145B, and the Nth downstream power supply 1210N provides power directly to the Nth output port 145N. Furthermore, current provided to each of the second output ports 145A-145N is sensed by a respective current sensing circuit 1230A-1230N. For example, the current sensing circuit 1230A senses an amount of current provided by downstream power supply 1210A to the second output port 145A, the current sensing circuit 1230B senses an amount of current provided by downstream power supply 1210B to the second output port 145B, and the current sensing circuit 1230N senses an amount of current provided by downstream power supply 1210N to the Nth output port 145N. Each downstream power supply 1210A-1210N includes a respective independent control mechanism 1225A-1225N configured to control power output by the respective downstream power supply 1210A-1210N based on respective current values sensed by current sensing circuits 1230A-1230N. Accordingly, the charging circuit 1200 illustrated in FIG. 14 is operable of regulating power output by the primary power supply 1205 and downstream power supplies 1210A-1210N to a plurality of peripheral devices connected to the first output port 135 and the second output ports 145A-145N.

In some embodiments, the charging circuit 1200 includes an additional current sensing circuit configured to sense an amount of current provided by the primary power supply 1205 to the at least one output port, such as USB port 135, included in output 1115. In other embodiments, the first independent control mechanism 1215 is configured to determine the amount of current provided by primary power supply 1205 directly to the at least on output port by subtracting a sum of current values sensed by current sensing circuits 1230A-1230N from the combined current value sensed by the aggregate current sensing circuit 1220. In some embodiments, the primary power supply 1205 is configured to provide power directly to more than one output port, as well as one or more downstream power supplies 1210A-1210N. In some embodiments, one or more downstream power supplies 1210A-1210N are operable to provide power directly to one or more other downstream power supplies 1210A-1210N.

Thus, aspects described herein provide, among other things, a receptacle with improved thermal management. Various features and advantages are set forth in the following claims.

What is claimed is:

1. A wiring device comprising:
an enclosure including a front cover and a rear cover;
a first printed circuit board (PCB) disposed within the enclosure;
a first direct current (DC) port;
a plurality of power electronics supported by a surface of the first PCB and configured to provide power to the first DC port; and
a heat sink in direct contact with at least one of the plurality of power electronics and disposed within an interior of the rear cover.

2. The wiring device of claim 1, wherein a surface of the rear cover includes a plurality of ventilation holes; and
wherein the heat sink is disposed between the plurality of power electronics and an interior of the surface that includes the plurality of ventilation holes.

3. The wiring device of claim 1, wherein the rear cover includes first and second indented portions for inserting the wiring device into an industry standard switch box.

4. The wiring device of claim 1, wherein the first DC port provides at least 50 watts of power to a load connected to the first DC port.

5. The wiring device of claim 1, wherein the heat sink is coupled to the at least one of the plurality of power electronics using a thermal adhesive.

6. The wiring device of claim 1, further comprising a secondary PCB that is electrically connected to the first PCB.

7. The wiring device of claim 6, further comprising a second DC port; and
wherein the first and second DC ports are supported by the secondary PCB.

8. The wiring device of claim 1, wherein the plurality of power electronics includes a transformer configured to output power at one or more DC voltage levels to the first DC port.

9. The wiring device of claim 8, wherein the transformer is a planar transformer.

10. The wiring device of claim 8, further comprising:
a switch connected to the transformer; and
a microcontroller including an electronic processor, the microcontroller configured to control, via the switch, delivery of power from the transformer to the first DC port.

11. The wiring device of claim 10, wherein at least one of the microcontroller and the switch are supported by the first PCB.

12. The wiring device of claim 1, wherein the heat sink is formed of aluminum.

13. The wiring device of claim 1, wherein the plurality of power electronics is disposed between the first PCB and the heat sink.

14. The wiring device of claim 1, further comprising a protection circuit supported by a surface of the first PCB.

15. An electrical receptacle comprising:
a rectifier configured to output power at a first direct current (DC) voltage level;
a transformer configured to convert the power from the first DC voltage level to a second DC voltage level, the transformer connected to a switching device;
a DC output port configured to receive power from the transformer at the second DC voltage level;
a microcontroller having an electronic processor configured to control a frequency at which the switching device is operated; and
a heat sink in direct contact with the transformer.

16. The electrical receptacle of claim 15, further comprising an enclosure formed by a front cover including an outlet face and a rear cover including a plurality of ventilation holes.

17. The electrical receptacle of claim 16, wherein the heat sink is arranged between the transformer and an interior surface of the rear cover such that the heat sink transfers heat from the transformer to an exterior of the electrical receptacle via the plurality of ventilation holes.

18. The electrical receptacle of claim 15, wherein the DC output port outputs at least 50 watts of power to a load connected to the DC output port.

19. The electrical receptacle of claim 15, further comprising a first printed circuit board (PCB) that supports the microcontroller and the transformer; and
a second PCB that supports the DC output port.

20. The electrical receptacle of claim 19, wherein the transformer is disposed between the first PCB and the heat sink.
